(19) United States
(12) Patent Application Publication
(10) Pub. No.: US 2012/0227792 A1
(43) Pub. Date: Sep. 13, 2012

(54) System and Method For Storing Panel-Specific Data onto a Wireless Tag Affixed to a Solar Panel

(75) Inventors: Hsi Sheng Chen, Fremont, CA (US); Yu-Chih Chen, Danville, CA (US)

(73) Assignee: E-Lightric, Inc., Monte Sereno, CA (US)

(21) Appl. No.: 13/414,365

(22) Filed: Mar. 7, 2012

Related U.S. Application Data
(60) Provisional application No. 61/451,980, filed on Mar. 11, 2011.

(51) Int. Cl. H01L 31/048; H01L 31/18

(52) U.S. Cl. 136/251; 29/890.033

(57) ABSTRACT

A solar panel includes a wireless tag affixed to the solar panel where the wireless tag includes a wireless communication interface, a memory, and an auxiliary communication port. The memory of the wireless tag is configured to store at least panel-specific data of the solar panel where the panel-specific data includes at least current-voltage characteristics of the solar panel. The data is stored onto the memory of the wireless tag through the auxiliary communication port and the stored data is accessible through the wireless communication interface of the wireless tag. In another embodiment, a method for storing panel-specific data in a solar panel includes placing the solar panel with a wireless tag affixed thereto in a solar panel characterization chamber to perform characterization test and storing panel-specific data of the solar panel, including at least current-voltage characteristics of the solar panel, in the memory of the wireless tag.

### CROSS-REFERENCE TO RELATED APPLICATIONS

This application claims the benefit of U.S. Provisional Patent Application Ser. No. 61/451,980, filed on Mar. 11, 2011, which application is incorporated herein by reference in its entirety.

### FIELD OF THE INVENTION

The invention relates to solar panels and, in particular, to a system and method for storing panel-specific data onto a wireless tag that is affixed to the solar panel.

### DESCRIPTION OF THE RELATED ART

A solar panel, also referred to as a photovoltaic panel, a solar module, or a photovoltaic module, is a packaged interconnected assembly of solar cells (also referred to as “solar wafers” or “photovoltaic cells”). FIG. 1(a) illustrates a conventional solar panel 1 including an assembly of solar cells 2 interconnected in a two-dimensional array. Solar panels use light energy (photons) from the sun to generate electricity through photovoltaic effect (i.e., the photo-electric effect). In a solar panel, the solar cells are connected electrically in series and in parallel to generate the desired output voltage and output current. More specifically, solar cells in a solar panel are connected in series to create an additive voltage and connected in parallel to yield a higher current.

FIG. 1(b) illustrates a single solar cell 2 including two bus bars 3 forming the electrical contacts of the solar cell. Solar cell 2 includes bus bars 3 formed on the front side (sun up) and also the back side (not shown) of the solar cell. Solar cells 2 are connected in series to form a column of the solar panel 1 by connecting the bus bars on the front side of one solar cell to the bus bars on the back side of the next solar cell and so on. Conductive wires or traces connect the bus bars at the ends of the columns of solar cells to form a serial or parallel connection from the columns of solar cells. Solar panel 1 includes external connectors for connecting to the most positive node (the Anode) and the most negative node (the Cathode) of the solar panel. The anode and cathode connectors are usually housed in a junction box 5 formed on the back side of the solar panel.

Because a single solar panel can only produce a limited amount of power, most photovoltaic installations involves connecting multiple solar panels into an array. A photovoltaic system or a solar system typically includes an array of solar panels, an inverter, batteries and interconnection wiring. Solar panels are interconnected, in series or parallel, or both, to create a solar array providing the desired peak DC voltage and current.

Once the solar cells are assembled into a panel, there is limited access to identify or monitor the individual solar cells. Should any one cell in a solar panel malfunctions, or any one solar panel in a solar array malfunctions, there will be a claim of warranty replacement or repair by the user. However, solar panel suppliers have only limited ability to identify defective solar panels in a solar panel installation in order to validate the warranty claim. This is because there is usually limited access to the solar panels in an installation. In order to determine the manufacturer or the origin of the defective solar panel, it is often necessary to disassemble the solar panel from the installation which can be very labor intensive and costly.

### SUMMARY OF THE INVENTION

According to one embodiment of the present invention, a solar panel includes a wireless tag affixed to the solar panel where the wireless tag includes a wireless communication interface, a memory, an antenna in electrical communication with the wireless communication interface, and an auxiliary communication port. The memory of the wireless tag is configured to store at least panel-specific data of the solar panel where the panel-specific data includes at least current-voltage characteristics of the solar panel. The data is stored onto the memory of the wireless tag through the auxiliary communication port and the stored data is accessible through the wireless communication interface of the wireless tag.

According to another embodiment of the present invention, a method for storing panel-specific data in a solar panel includes affixing a wireless tag to the solar panel where the wireless tag includes a wireless communication interface, a memory, an antenna in electrical communication with the wireless communication interface, and an auxiliary communication port; placing the solar panel with the wireless tag affixed thereto in a solar panel characterization chamber; performing characterization test on the solar panel; recording performance data of the solar panel, including at least current-voltage characteristics of the solar panel, at a host processor; transferring panel-specific data of the solar panel, including at least current-voltage characteristics of the solar panel, from the host processor to the wireless tag through the auxiliary communication port of the wireless tag; and storing the panel-specific data of the solar panel in the memory of the wireless tag.

The present invention is better understood upon consideration of the detailed description below and the accompanying drawings.

### BRIEF DESCRIPTION OF THE DRAWINGS

FIG. 1(a) illustrates a conventional solar panel including an assembly of solar cells interconnected in a two-dimensional array.

FIG. 1(b) illustrates a single solar cell including two bus bars forming the electrical contacts of the solar cell.

FIG. 2 illustrates a solar panel with a wireless tag affixed thereto according to embodiments of the present invention.

FIG. 3 illustrates a solar panel final test system and a tag data recording system for storing panel-specific data onto a wireless tag affixed to the solar panel according to embodiments of the present invention.

FIG. 4 illustrates a solar panel with a wireless tag affixed thereto where the stored data is accessed by a remote reader according to embodiments of the present invention.

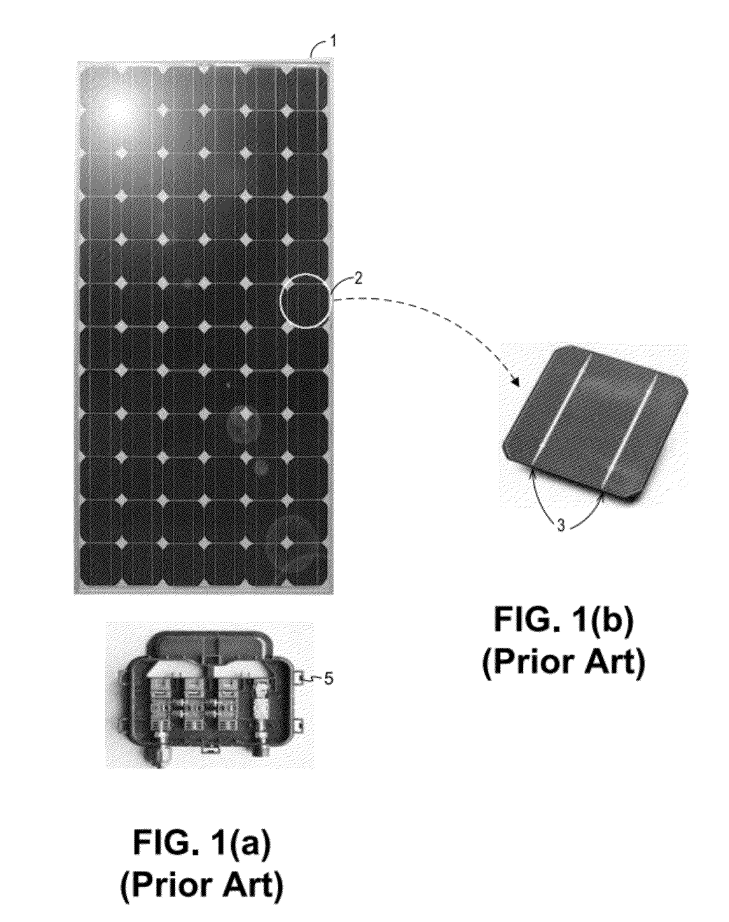

### DETAILED DESCRIPTION OF THE PREFERRED EMBODIMENTS

According to one aspect of the present invention, a system and method is provided to store panel-specific data onto a wireless tag that is affixed to a solar panel. The wireless tag is affixed to the solar panel and data associated with the solar panel is stored onto a memory of the wireless tag during the final testing stage of the solar panel. Thereafter, the stored data can be read via a wireless reader and the stored data can be used to uniquely identify the solar panel, without having to disassemble or removing the solar panel from the installation.

In conventional solar panel manufacturing processes, the assembled solar panels are subjected to final testing and characterization at the end of the production line. More specifically, a completed solar panel is placed into a solar panel characterization chamber. The solar panel may be exposed to different operating environments, such as bright light, high and low temperatures and high and low humidity. The performance characteristics of the solar panel are read out and recorded by a host processor. For instance, the current-voltage characteristic of the solar panel may be recorded by the host processor.

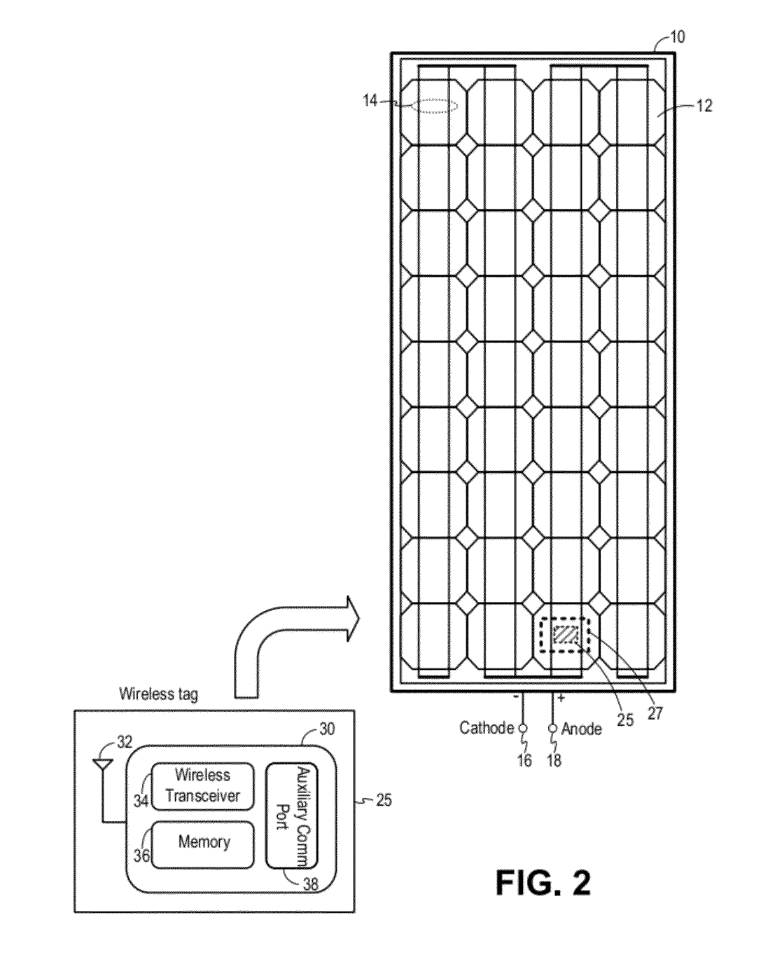

In accordance with embodiments of the present invention, a wireless tag is affixed to or embedded in a solar panel during the manufacturing process of the solar panel. Thus, the wireless tag is tamper resistance which has the benefits of deterring or eliminating thefts of the solar panel or counterfeits. FIG. 2 illustrates a solar panel with a wireless tag affixed thereto according to embodiments of the present invention. Referring to FIG. 2, a solar panel 10 includes an assembly of a two-dimensional array of interconnected solar cells 12. In the present illustration, each solar cell 12 includes two conductive traces (bus bars) 14 formed on the front side and two conductive traces (bus bars) formed on the back side (not shown) of the solar cell. In the present illustration, the bus bars 14 are connected at the ends of the solar panel 10 to form a serial connection of solar cells. Other combinations of solar cells, including serial or parallel combinations, are also possible by connecting the bus bars accordingly. Solar panel 10 includes external connectors 16 and 18 for connecting to the most positive node (the Anode) and the most negative node (the Cathode) of the solar panel.

The solar panel 10 further includes an electrical junction box for housing the external electrical connectors 16, 18 to the anode and cathode terminals of the solar panel. More specifically, the junction box houses the electrical connections from the electrical contacts of the solar cells to cable connectors for electrical connection out of the panel. The junction box is formed on the back side of the solar panel and includes a junction box interface where exposed conductive traces to the solar cells, i.e., not covered by the back sheet of the solar panel, are located. A junction box housing is placed on top of the junction box interface and includes connectors, such as metal screws, for making electrical contact with the conductive traces, thereby forming the external connectors of the solar panel. In the present description, the dotted line box 27 in FIG. 2 denotes the junction box of the solar panel which includes the junction box interface with exposed conductive traces, the junction box housing and the connectors for making electrical connections therein.

In embodiments of the present invention, a wireless tag 25 is affixed to or embedded in the solar panel 10. In some embodiments, the wireless tag is placed between the top plate and the back sheet of the solar panel 10. In other embodiments, the wireless tag is housed in the junction box 27 of the solar panel 10. In the present description, a wireless tag being “affixed to” a solar panel describes embedding the wireless tag between the top plate and the back sheet of the solar panel, embedding the wireless tag in the junction box of the solar panel, or affixing the wireless tag to the solar panel is other ways. The exact method of affixing or embedding the wireless tag in the solar panel is not critical to the practice of the present invention.

The wireless tag 25 includes a wireless element 30 and an antenna 32 for facilitating wireless communication with a wireless reader device. The antenna 32 can be formed on the wireless tag. Alternately, the antenna 32 is formed on or embedded within the solar panel and is electrically connected to the wireless element 30. The wireless element 30 includes at least a wireless transceiver 34 and a memory circuit 36. The wireless transceiver 34 facilitates wireless communication of the wireless tag, such as through radio frequency (RF) communication. In the present embodiment, the wireless element 30 further includes an auxiliary communication port 38. Auxiliary communication port 38 may be a wired communication port or a wireless communication port. In one embodiment, the auxiliary communication port 38 is a wired serial data port. In other embodiments, the auxiliary communication port 38 may be a parallel data bus having a desired data bit width. The wireless transceiver 30 and the auxiliary communication port 38 communicate with the memory circuit 36 over an interface bus.

In the present embodiments, the wireless tag is capable of wireless communication employing one or more of the wireless communication technologies currently known or to be developed. For example, in one embodiment, the wireless tag implements wireless communication through radio frequency (RF) communication, such as based on the RFID (radio frequency identification) technology, or wireless local area network communication technology, such as Wi-Fi technology. In another embodiment, the wireless tag employs Bluetooth radio technology. Bluetooth radio technology is an open specification for short-range wireless communication of data and voice that operates in the unlicensed Industrial, Scientific, Medical (ISM) band at 2.4 Gigahertz (GHz). The gross data rate may be 1 megabit per second (Mb/s). In yet another embodiment, the wireless tag employs ZigBee communication technology. ZigBee is a wireless control technology utilizing a low-cost, low power, wireless mesh networking protocol that is especially useful in control and monitoring applications. In yet another embodiment, the wireless tag employs WiMAX communication.

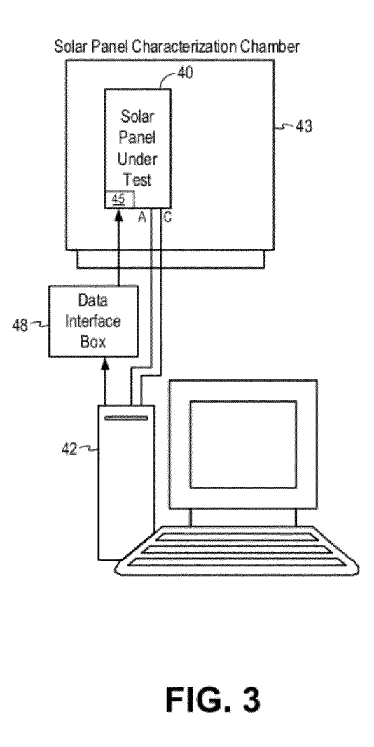

After having the wireless tag embedded into the solar panel and after the completion of the manufacturing process of the solar panel, the solar panel is subjected to final testing. FIG. 3 illustrates a solar panel final test system and a tag data recording system for storing panel-specific data onto a wireless tag embedded in the solar panel. Referring to FIG. 3, at the final test stage, a solar panel 40 is placed in a solar panel characterization chamber 43 and subjected to various environmental conditions while undergoing final testing. The performance characteristics of the solar panel, including the output voltage and the output current of the solar panel, are recorded by a host processor 42. For instance, the host processor 42 is coupled to the anode (A) and cathode (C) terminals of the solar panel 40 to record the output current and output voltage from the solar panel under different environmental conditions. In some embodiments, the host processor 42 records the current-voltage (I-V) characteristics of the solar panel 40. The current-voltage characteristics of the solar panel describe the output current and output voltage relationship of the solar panel under different loading conditions. In operation, a desired operating point for the solar panel is selected so that the solar panel is operated at the desired current-voltage set point.

The I-V characteristics of the solar panel can be expressed as a family of I-V curves. More specifically, the I-V characteristics of a solar panel are unique to the solar panel and each solar panel will have a different set of I-V data. Thus, the I-V data of a solar panel can be used as a unique identifier of the solar panel.

According to one embodiment of the present invention, a tag data recording system is incorporated with the solar panel final test system to facilitate storage of panel-specific data onto the wireless tag embedded in the solar panel. In the present embodiment, the tag data recording system includes a data interface box 48 connected between the host processor 42 and the auxiliary communication port of the wireless tag 45 embedded in the solar panel 40. The data interface box 48 operates to transfer panel-specific data collected by the host processor 42 to the wireless tag 45. The data is stored in the memory circuit of the wireless element of the wireless tag. The data interface box 48 may be implemented using hardware, software or a combination of hardware and software. In one embodiment, data interface box 48 performs data format conversion to generate output data in a serial data format to be transmitted through wired communication to the auxiliary data port of the wireless tag.

In the present illustration, the auxiliary communication port of the wireless tag 45 is a wired serial data port and data interface box 48 connects to the auxiliary communication port over a pair of data wires supporting duplex communications. In other embodiments, the auxiliary communication port of the wireless tag 45 may be a wireless data port. In that case, data interface box 48 communicates with the auxiliary communication port of the wireless tag 45 through wireless communication, such as RF or Bluetooth communication.

In one embodiment, the data interface box 48 is configured to transfer identification data of the solar panel to be stored in the memory circuit of the wireless tag 45. A salient feature of the tag data recording system of the present invention is that the data interface box 48 provides the current-voltage (I-V) characteristics of the solar panel under test to the wireless tag 45 for storage. The I-V data of the solar panel is measured at the final test stage in the characterization chamber 43. The I-V data of the solar panel under test 40 is measured and recorded by the host processor 42. Data interface box 48 is configured to retrieve the I-V data of the solar panel under test and transfer the I-V data of the solar panel to the wireless tag 45 to be stored in the memory circuit of the wireless tag 45. Because the I-V characteristics of a solar panel is unique to the solar panel, the I-V data can serve as a birth certificate for the solar panel for uniquely identifying the solar panel. Accordingly, by using the tag data recording system in accordance with embodiments of the present invention, each solar panel with a wireless tag affixed thereto is stored with the panel's own I-V data as an unique identifier during the final test stage.

In others embodiments, the data interface box 48 is also configured to transfer other identification data to be stored on the wireless tag 45. The other identification data includes the identification (ID) of the manufacturer of solar panel, the identification (ID) of the manufacturer of solar cells in the solar panel, the dates, such as month and year, of the manufacture of solar cells in the solar panel and of the solar panel, and the country or countries of origin for the solar cells in the solar panel and for the solar panel.

The identification data being stored may further include the wattage, the maximum output current, the maximum output voltage and the fill factor (FF) for the solar panel. The identification data may also include the unique serial number and the model number of the solar panel. The identification data may also include the date and year of obtaining International Electrotechnical Commission (IEC) solar panel qualification certificate. Finally, the identification data may include the name of the test lab issuing the IEC certificate.

Accordingly, with the solar panel processed through final testing using the tag data recording system, a solar panel thus manufactured will have panel-specific data stored on the embedded wireless tag. The stored data includes identification data or operating parameters of the solar panel. In some embodiments, the I-V data of the solar panel is stored and used as a unique identifier or a birth certificate of the solar panel.

Subsequent to final testing, the solar panel is then available to be installed at an installation site. When the solar panel is installed in a solar array, the wireless tag with panel-specific data stored thereon provides many advantageous functions.

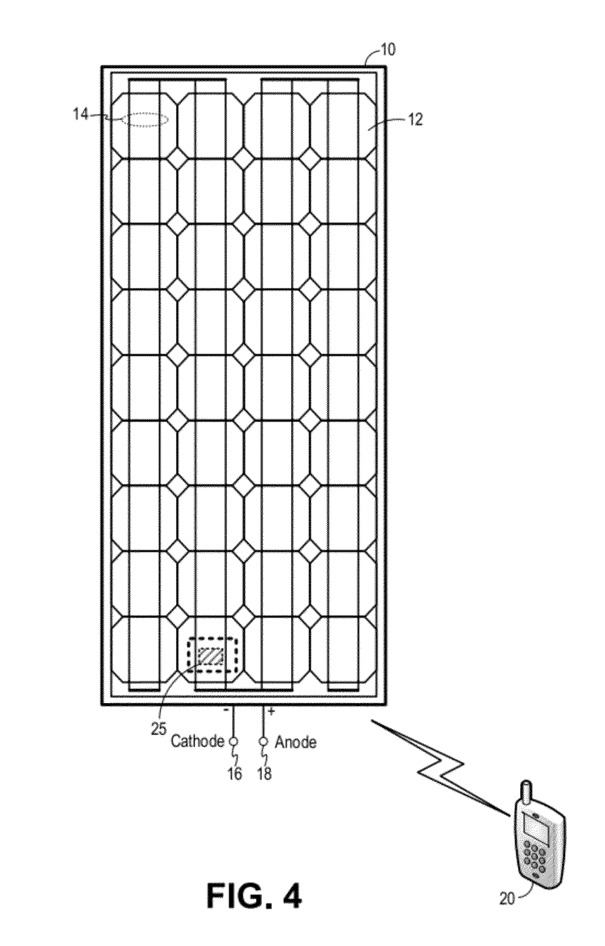

First, the data stored on the wireless tag may be retrieved using a wireless reader device brought within the communication range of the wireless tag, as shown in FIG. 4. Identification and performance data of the solar panel can be read without having to disassemble the solar panel from the installation.

Second, the panel-specific data can be used to uniquely identify the solar panel. For instance, the stored panel-specific data can be used to determine the manufacturer or country of origin of the solar panel. In particular, the I-V data of a solar panel, which is unique to the solar panel, can be used to definitively identify a solar panel. The retrieved I-V data of the solar panel can be compared with recorded I-V data associated with that solar panel for positive identification. In this manner, an operator may definitively determine the manufacturer or origin of a solar panel, such as for the purpose of warranty claims, without having to remove the solar panel from the installation.

Third, the panel-specific data can be used for performance monitoring and enhancement of the solar panel. For instance, the solar panel may be tested in the field and when the performance of the solar panel is not as expected based on the stored I-V data on the wireless tag, the operator may adjust the loading to the solar panel to optimize the solar panel performance.

The above detailed descriptions are provided to illustrate specific embodiments of the present invention and are not intended to be limiting. Numerous modifications and variations within the scope of the present invention are possible. The present invention is defined by the appended claims.

We claim:

1. A solar panel comprising:
a wireless tag affixed to the solar panel, the wireless tag comprising a wireless communication interface, a memory, an antenna in electrical communication with the wireless communication interface, and an auxiliary communication port,
wherein the memory of the wireless tag is configured to store at least panel-specific data of the solar panel, the panel-specific data comprising at least current-voltage characteristics of the solar panel, the data being stored onto the memory of the wireless tag through the auxiliary communication port and the stored data being accessible through the wireless communication interface of the wireless tag.

2. The solar panel of claim 1, wherein the solar panel comprises:
an assembly of interconnected photovoltaic cells;
a top plate configured to affix to a front side (sun up side) of the assembly of interconnected photovoltaic cells; and
a back sheet configured to affix to a back side of the assembly of interconnected photovoltaic cells,
wherein the wireless tag is embedded between the top plate and the back sheet of the solar panel.

3. The solar panel of claim 1, wherein the solar panel comprises a junction box formed on a back side of the solar panel, and the wireless tag is embedded in the junction box.

4. The solar panel of claim 1, wherein the current-voltage characteristics of the solar panel is used as a unique identifier of the solar panel.

5. The solar panel of claim 1, wherein the panel-specific data further comprises an output current and an output voltage of the solar panel.

6. The solar panel of claim 1, wherein the panel-specific data further comprises one or more of: an identification (ID) of the manufacturer of solar panel, an identification (ID) of the manufacturer of solar cells in the solar panel, the dates of the manufacture of solar cells in the solar panel and of the solar panel, and the country or countries of origin for the solar cells in the solar panel and for the solar panel.

7. The solar panel of claim 1, wherein the panel-specific data further comprises one or more of: the wattage, the maximum output current, the maximum output voltage, the fill factor (FF) for the solar panel, the unique serial number of the solar panel, the model number of the solar panel, the date and year of obtaining International Electrotechnical Commission (IEC) solar panel qualification certificate, and the name of the test lab issuing the IEC certificate.

8. The solar panel of claim 1, wherein the auxiliary communication port comprises a wired serial data port.

9. The solar panel of claim 1, wherein the auxiliary communication port comprises a wireless data port.

10. A method for storing panel-specific data in a solar panel, comprising:
affixing a wireless tag to the solar panel, the wireless tag comprising a wireless communication interface, a memory, an antenna in electrical communication with the wireless communication interface, and an auxiliary communication port;
placing the solar panel with the wireless tag affixed thereto in a solar panel characterization chamber;
performing characterization test on the solar panel;
recording performance data of the solar panel, including at least current-voltage characteristics of the solar panel, at a host processor;
transferring panel-specific data of the solar panel, including at least current-voltage characteristics of the solar panel, from the host processor to the wireless tag through the auxiliary communication port of the wireless tag; and
storing the panel-specific data of the solar panel in the memory of the wireless tag.

11. The method of claim 10, further comprising:
retrieving the stored data in the memory of the wireless tag through the wireless communication interface of the wireless tag.

12. The method of claim 10, wherein affixing a wireless tag to the solar panel comprises embedding the wireless tag between a top plate and a back sheet of the solar panel.

13. The method of claim 10, wherein affixing a wireless tag to the solar panel comprises embedding the wireless tag in a junction box formed on a back side of the solar panel.

14. The method of claim 10, wherein the current-voltage characteristics of the solar panel is used as a unique identifier of the solar panel.

15. The method of claim 10, wherein the panel-specific data further comprises an output current and an output voltage of the solar panel.

16. The method of claim 10, wherein the panel-specific data further comprises one or more of: an identification (ID) of the manufacturer of solar panel, an identification (ID) of the manufacturer of solar cells in the solar panel, the dates of the manufacture of solar cells in the solar panel and of the solar panel, and the country or countries of origin for the solar cells in the solar panel and for the solar panel.

17. The method of claim 10, wherein the panel-specific data further comprises one or more of: the wattage, the maximum output current, the maximum output voltage, the fill factor (FF) for the solar panel, the unique serial number of the solar panel, the model number of the solar panel, the date and year of obtaining International Electrotechnical Commission (IEC) solar panel qualification certificate, and the name of the test lab issuing the IEC certificate.

18. The method of claim 10, wherein transferring panel-specific data of the solar panel from the host processor to the wireless tag through the auxiliary communication port of the wireless tag comprises transferring panel-specific data of the solar panel from the host processor to the wireless tag through a wired serial data port.

19. The method of claim 10, wherein transferring panel-specific data of the solar panel from the host processor to the wireless tag through the auxiliary communication port of the wireless tag comprises transferring panel-specific data of the solar panel from the host processor to the wireless tag through a wireless data port.
